(19) United States
(12) Patent Application Publication
(10) Pub. No.: US 2025/0212559 A1
(43) Pub. Date: Jun. 26, 2025

(54) LIGHT EMITTING DIODE AND LIGHT EMITTING DEVICE

(71) Applicant: Tianjin Sanan Optoelectronics Co., Ltd., Tianjin (CN)

(72) Inventors: Di GAO, Tianjin (CN); Yuren PENG, Tianjin (CN); Huanshao KUO, Tianjin (CN)

(73) Assignee: Tianjin Sanan Optoelectronics Co., Ltd., Tianjin (CN)

(21) Appl. No.: 18/974,547

(22) Filed: Dec. 9, 2024

(30) Foreign Application Priority Data
Dec. 26, 2023 (CN) 202311810142.X

(51) Int. Cl. H10H 20/814; H10H 20/812; H10H 20/825; H10H 20/833

(52) U.S. Cl. CPC H10H 20/814; H10H 20/812; H10H 20/8252; H10H 20/833

(57) ABSTRACT

The disclosure relates to a light emitting diode and a light emitting device. The light-emitting diode includes an epitaxial structure, a P-type window layer, a transparent conductive layer, and an N-type electrode. The epitaxial structure includes a P-type semiconductor layer, a light emitting layer, and an N-type semiconductor layer stacked in sequence. The P-type window layer is disposed under the P-type semiconductor layer, the transparent conductive layer is disposed under the P-type window layer, and the N-type electrode is disposed on the N-type semiconductor layer, in which a current density of the light-emitting diode is defined as J A/cm², a minimum spacing between a projection of the N-type electrode on the N-type semiconductor layer and a projection of the P-type window layer on the N-type semiconductor layer is L μm, and a range of L:J is 0.3 to 1.5. The wall-plug-efficiency and quality of the light-emitting diode can be improved.

### CROSS-REFERENCE TO RELATED APPLICATION

This application claims the priority benefit of China application serial no. 202311810142.X, filed on Dec. 26, 2023. The entirety of the above-mentioned patent application is hereby incorporated by reference herein and made a part of this specification.

### BACKGROUND

### Technical Field

The disclosure relates to the field of semiconductor manufacturing technology, and particularly relates to a light emitting diode and a light emitting device.

### Description of Related Art

A light emitting diode (LED) is a semiconductor light emitting element, usually made of semiconductors such as GaN, GaAs, GaP, GaAsP, and the core thereof is a PN junction with light emitting properties. The LEDs have the advantages of high luminous intensity, high efficiency, small size, and long service life, and are considered to be one of the most promising light sources currently. The LEDs have been widely used in fields such as lighting, monitoring and command, high-definition broadcasting, high-end cinemas, office displays, conference interaction, and virtual reality.

The existing light-emitting diode structure mainly includes three semiconductor layers, namely, a p-type semiconductor layer, an n-type semiconductor layer, and an active layer, in which the p-type semiconductor layer may provide holes, while the n-type semiconductor layer may provide electrons. Under the action of an external electric field, holes and electrons in the light-emitting diode structure recombine and generate light in the active layer area, converting electrical energy into light energy. The wall-plug-efficiency of the light emitting diode is one of the important performance indicators for measuring the quality of the light emitting diode. Therefore, how to improve the wall-plug-efficiency of the light emitting diode is an important research direction for persons skilled in the art.

It should be noted that the information disclosed in this background technology section is only intended to increase the understanding of the overall background of the disclosure, and should not be regarded as admitting or suggesting in any form that the information constitutes the related art known to persons skilled in the art.

### SUMMARY

The disclosure provides a light emitting diode, which includes an epitaxial structure, at least one P-type window layer, a transparent conductive layer, and at least one N-type electrode. The epitaxial structure includes a P-type semiconductor layer, a light emitting layer, and an N-type semiconductor layer stacked in sequence from bottom to top. The P-type window layer is disposed under the P-type semiconductor layer, the transparent conductive layer is disposed under the P-type window layer, and the N-type electrode is disposed on the N-type semiconductor layer, in which a current density of the light-emitting diode is defined as J A/cm², a minimum spacing between a projection of the N-type electrode on the N-type semiconductor layer and a projection of the P-type window layer on the N-type semiconductor layer is L μm, and a range of L:J is 0.3 to 1.5.

The disclosure further provides a light emitting device, which adopts the light emitting diode as described above.

An embodiment of the disclosure provides the light emitting diode and the light emitting device, which improve the wall-plug-efficiency of the light emitting diode and the quality of the light emitting diode by controlling the ratio of the spacing to the current density to be set in a range of 0.3 to 1.5.

Other features and beneficial effects of the disclosure will be described in the following description, and some of the technical features and beneficial effects may be notably derived from the description or understood by implementing the disclosure.

### BRIEF DESCRIPTION OF THE DRAWINGS

In order to more clearly illustrate the embodiments of the disclosure or the technical solutions in the related art, the following briefly introduces the drawings required to be used in the embodiments or the description of the related art. Certainly, some of the drawings described below are some embodiments of the disclosure. For ordinary technicians in this field, other drawings may be obtained based on the drawings without any creative effort.

FIG. 1A is a schematic structural view of a top view of a light emitting diode provided in an embodiment of the disclosure.

FIG. 1B is an enlarged schematic view of a region B in FIG. 1A.

FIG. 1C is a schematic structural view of a top view of an N-type electrode in FIG. 1A.

FIG. 2 is a schematic structural view of a cross-sectional view taken along a cutting line F-F in FIG. 1B.

FIG. 3 to FIG. 10 are schematic structural views of the light emitting diode shown in FIG. 2 at various stages during a preparation process.

### DESCRIPTION OF THE EMBODIMENTS

In order to make the purpose, technical solution, and advantages of the embodiments of the disclosure clearer, the technical solution in the embodiments of the disclosure will be clearly and completely described below together with the drawings in the embodiments of the disclosure. Certainly, the described embodiments are only part of the embodiments of the disclosure, but not all of the embodiments. The technical features designed in different embodiments of the disclosure described below may be combined with each other as long as the features do not conflict with each other; based on the embodiments of the disclosure, all other embodiments obtained by ordinary technicians in this field without making any creative effort are within the scope of protection of the disclosure.

In the description of the disclosure, it should be understood that the directions or positional relationships indicated by the terms “center”, “lateral”, “upper”, “lower”, “left”, “right”, “vertical”, “horizontal”, “top”, “bottom”, “inner”, “outer” and the like are based on the directions or positional relationships shown in the accompanying drawings, which is only for the convenience of describing the disclosure and simplifying the description, and does not indicate or imply that the devices or components mentioned necessarily have a specific orientation, or be constructed and operated in a specific orientation, and thus should not be understood as limiting the disclosure. In addition, the terms “first” and “second” are used for descriptive purposes only and should not be understood as indicating or implying relative importance or implicitly indicating the quantity of the indicated technical features. Therefore, features defined as “first” or “second” may explicitly or implicitly include one or more of such features. In the description of the disclosure, unless otherwise specified, “plurality” means two or more. In addition, the term “include” and any variations thereof all mean “include at least”.

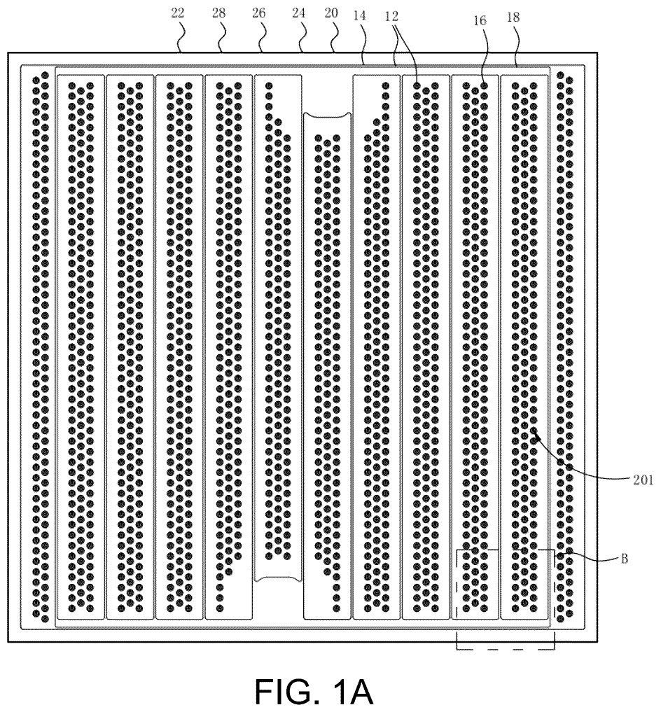

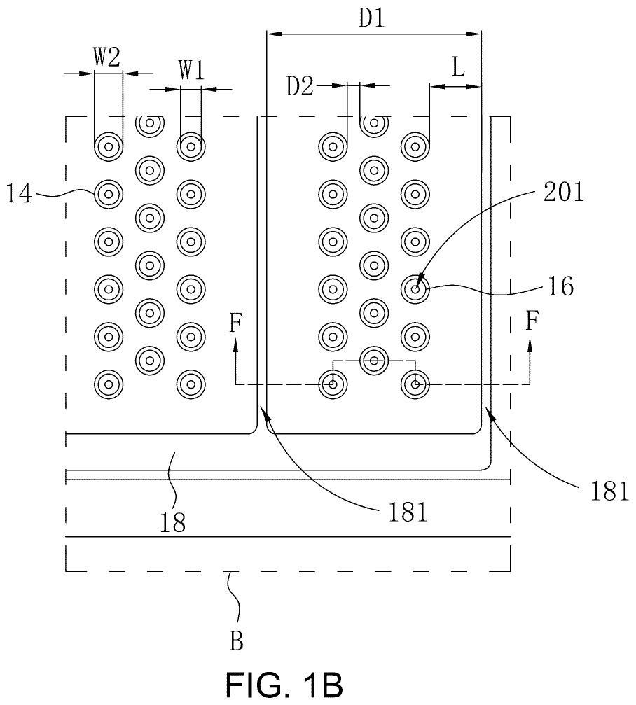

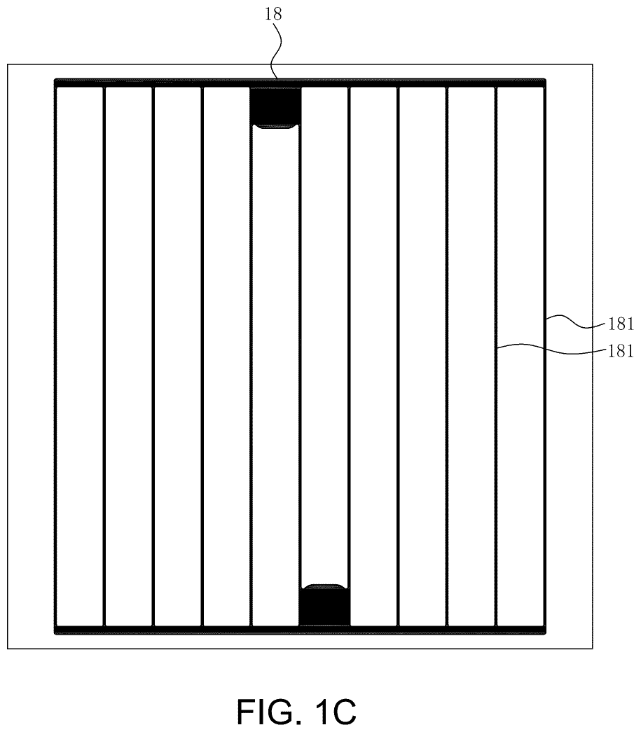

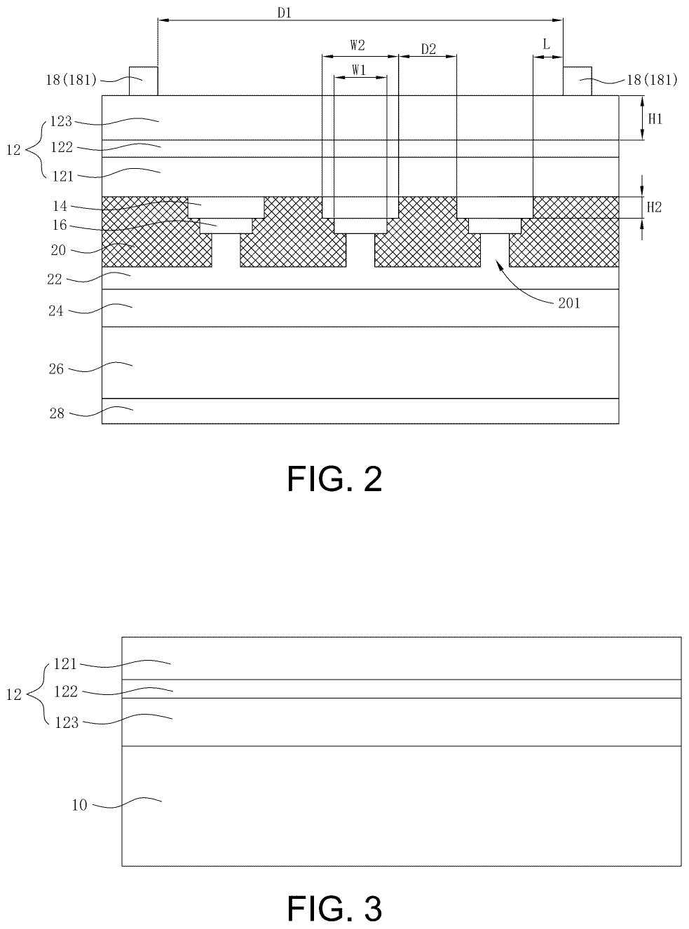

Please refer to FIG. 1A, FIG. 1B, FIG. 1C, and FIG. 2. FIG. 1A is a schematic structural view of a top view of a light emitting diode provided in an embodiment of the disclosure, FIG. 1B is an enlarged schematic view of a region B in FIG. 1A, FIG. 1C is a schematic structural view of a top view of an N-type electrode 18 in FIG. 1A, and FIG. 2 is a schematic structural view of a cross-sectional view taken along a cutting line F-F in FIG. 1B. To achieve at least one of the above advantages or other advantages, an embodiment of the disclosure provides a light emitting diode. As shown in the drawings, the light emitting diode may at least include an epitaxial structure 12, a P-type window layer 14, a transparent conductive layer 16, and an N-type electrode 18.

The epitaxial structure 12 includes a P-type semiconductor layer 121, a light emitting layer 122, and an N-type semiconductor layer 123 stacked in sequence from bottom to top.

The P-type semiconductor layer 121 may provide holes to the light emitting layer 122 under the action of power. In some embodiments, the P-type semiconductor layer 121 includes a P-type doped nitride layer, an arsenide layer, or a phosphide layer. The P-type impurities may include one of Mg, Zn, C or a combination thereof. The P-type semiconductor layer 121 may be a single-layer structure or a multi-layer structure, and the multi-layer structure has different compositions.

The light emitting layer 122 may be a quantum well (QW for short) structure. In some embodiments, the light emitting layer 122 may also be a multiple quantum well (MQW for short) structure, in which the multiple quantum well structure includes multiple quantum well layers and multiple quantum barrier layers alternately arranged in a repeated manner, for example, the structure may be a multiple quantum well structure of GaN/AlGaN, InAlGaN/InAlGaN, InGaN/AlGaN, AlGaInp/AlGaInP, or AlInGaAs/AlGaAs. In addition, the composition and thickness of the well layer in the light emitting layer 122 determine the wavelength of the generated light. In order to improve the light emitting efficiency of the light emitting layer 122, it may be achieved through operations such as changing the depth of the quantum well, the quantity of layers of the paired quantum wells and quantum barriers, the thickness, and/or other features in the light emitting layer 122.

The N-type semiconductor layer 123 may provide electrons to the light emitting layer 122 under the action of power. In some embodiments, the N-type semiconductor layer 123 includes an N-type doped nitride layer, an arsenide layer, or a phosphide layer. The N-type impurities may include one of Si, Ge, and Sn or a combination thereof. In some embodiments, a thickness H1 of the N-type semiconductor layer 123 is in a range of 2 μm to 4 μm. Optionally, the thickness H1 of the N-type semiconductor layer 123 is in a range of 2.5 μm to 3 μm. Considering the poor stability of the roughening process, the depth may be too deep after roughening, which may damage the light emitting layer 122 and cause leakage, the thickness H1 of the N-type semiconductor layer 123 should not be less than 2.5 μm.

The P-type window layer 14 is disposed under the P-type semiconductor layer 121. The material of the P-type window layer 14 may be GaP. The main function of the P-type window layer 14 is to perform current expansion, and the thickness thereof affects the current expansion performance and the overall light output performance. If a thickness H2 of the P-type window layer 14 is too large, then the light emission is affected, resulting in lower brightness; if the thickness H2 of the P-type window layer 14 is too small, then the current expansion performance is caused to deteriorate. Therefore, the thickness H2 of the P-type window layer 14 may be in a range of 200 angstroms (Å) to 3000 angstroms. Optionally, the thickness H2 of the P-type window layer 14 is in a range of 600 to 2000 angstroms.

The transparent conductive layer 16 is disposed under the P-type window layer 14. The transparent conductive layer 16 is made of a transparent conductive material, the transparent conductive material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto.

The N-type electrode 18 is disposed on the N-type semiconductor layer 123. The N-type electrode 18 may be a single-layer structure, a double-layer structure, or a multi-layer structure. The material of the N-type electrode 18 may be a metal material, such as Cr, Pt, Au, Ni, Ti, Al, and other metal materials.

The current density of the light emitting diode is defined as J A/cm², and the minimum spacing between the projection of the N-type electrode 18 on the N-type semiconductor layer 123 and the projection of the P-type window layer 14 on the N-type semiconductor layer 123 is L μm. The current density J A/cm² may refer to the current received by the epitaxial structure 12 divided by the area of the light emitting region. The light emitting region does not include the area of the cutting lane. The area of the light emitting region refers to the area of the epitaxial structure 12, for example. Considering that when the distance between the N-type electrode 18 and the P-type window layer 14 is shortened (that is, L is reduced), the lateral resistance of PN is reduced due to the shortening of the transmission distance between the N-type electrode 18 and the P-type window layer 14, thereby achieving the effect of reducing the voltage. However, it is also caused that the light emitting layer 122 is closer to the N-type electrode 18, so that the light is blocked by the metal and absorbed, resulting in lower overall brightness. If the ratio of brightness reduction is too large, then the effect of improving WPE (wall-plug-efficiency) is not achieved. Therefore, for light-emitting diodes, the conversion efficiency cannot be improved simply by reducing the spacing L; instead, the voltage drop and the brightness drop have to be considered comprehensively. Therefore, when the spacing L is in a range of 10 μm to 30 μm, controlling a ratio of L:J to be in a range of 0.3 to 1.5 is beneficial to reducing the voltage and improving the wall-plug-efficiency. In addition, when the thickness H2 of the P-type window layer 14 is in a range of 200 angstroms to 3000 angstroms, a ratio of L:J being in a range of 0.3 to 1.5 provides a better wall-plug-efficiency.

When the current density J A/cm² is less than 27 A/cm², the amount of light near the N-type electrode 18 is small, reducing the spacing L may cause small influence on light shading and light absorption, and the attenuation amplitude of the LOP (loss of power) is less than the amplitude of the voltage reduction, which leads to an increase in the wall-plug-efficiency WPE. In this condition, the optimal value range of the spacing L is 10 μm to 25 μm. As the spacing L decreases from 25 μm, the conversion efficiency improves.

When the current density J A/cm²>27 A/cm², the amount of light near the N-type electrode 18 is more, reducing the spacing L may cause greater influence on light shading and light absorption, and the attenuation amplitude of the LOP (loss of power) is greater than the amplitude of the voltage reduction, which leads to a decrease in the wall-plug-efficiency WPE. In this condition, the optimal value range of the spacing L is 15 μm to 30 μm. If the spacing L is less than 15 μm, then the conversion efficiency decreases.

When the width of the transparent conductive layer 16 is defined as W1 and the width of the P-type window layer 14 is defined as W2, it is preferred that W1≤W2. Since an ohmic contact is formed between the transparent conductive layer 16 and the P-type window layer 14, if W1>W2, the brightness of the light emitting diode is reduced. Optionally, the range of W2 is 10μm to 30 μm. If the quantity of the P-type window layers 14 is plural, then the width W2 of the P-type window layer 14 refers to the width W2 of a single P-type window layer 14. Similarly, the width W1 of the transparent conductive layer 16 refers to the width W1 of a single transparent conductive layer 16 located on one P-type window layer 14. Optionally, the range of W2 is 15 μm to 20 μm, such as 16 μm.

The N-type electrode 18 may include a plurality of finger electrodes 181, and a spacing D1 between two adjacent finger electrodes 181 is in a range of 90 μm to 130 μm. As shown in FIG. 1C, the region filled with black shadow in FIG. 1C is the region where the N-type electrode 18 is located. The plurality of finger electrodes 181 are arranged side by side from left to right in the drawing, and the spacing DI between two adjacent finger electrodes 181 is the width of the remaining blank area. Since the current expansion capability on the side close to the N-type electrode 18 is almost fixed, if the spacing DI is too large (such as greater than 130 μm), then the current expansion between PN is deteriorated, and the operating voltage needs to be increased; if the spacing D1 is too small (for example, less than 90 μm), then more finger electrodes 181 need to be provided, which increases the light shielding area and reduce the brightness. Optionally, the spacing DI between two adjacent finger electrodes 181 is in a range of 110 μm to 125 μm. In some embodiments, the minimum spacing L may refer to the minimum spacing between the projection of the N-type electrode 18 on the N-type semiconductor layer 123 and the projection of the P-type window layer 14 on the N-type semiconductor layer 123 along the parallel arrangement direction of the plurality of finger electrodes 181.

The quantity of the P-type window layers 14 is plural, and the spacing D2 between two adjacent P-type window layers 14 is in a range of 5 μm to 15 μm. If the spacing D2 is too large (such as greater than 15 μm), then the current expansion between PN is deteriorated, and the operating voltage needs to be increased; if the spacing D2 is too small (for example, less than 5 μm), then the quantity of the window layers 14 is increased, and the quantity of the transparent conductive layers 16 is also increase accordingly, thereby affecting the light output brightness of the light emitting diode. Optionally, the spacing D2 between two adjacent P-type window layers 14 is in a range of 7 μm to 12 μm.

The light emitting diode further includes an insulative protective layer 20, a metal reflection layer 22, a bond layer 24, a substrate 26, and a backside metal electrode 28.

The insulative protective layer 20 covers the P-type semiconductor layer 121, the P-type window layer 14, and the transparent conductive layer 16. The insulative protective layer 20 has an opening 201. The material of the insulative protective layer 20 includes a non-conductive material. The non-conductive material is preferably an inorganic material or a dielectric material. The inorganic material may include silica gel. The dielectric material includes an electrically insulating material such as aluminum oxide, silicon nitride, silicon oxide, titanium oxide, or magnesium fluoride. For example, the insulative protective layer 20 may be silicon dioxide, silicon nitride, titanium oxide, tantalum oxide, niobium oxide, barium titanate, or a combination thereof, in which the combination may be a Bragg reflector (DBR) formed by repeatedly stacking two materials with different refractive indices.

The metal reflection layer 22 is disposed under the insulative protective layer 20 and is connected to the transparent conductive layer 16 through the opening 201. The metal reflection layer 22 may be made of metal material, such as Ag metal. The bond layer 24 is disposed under the metal reflection layer 22. The bond layer 24 is used to bond the substrate 26 and the metal reflection layer 22 to improve the connection strength of the overall structure. The substrate 26 is disposed under the bond layer 24, that is, the bond layer 24 is positioned between the substrate 26 and the metal reflection layer 22. The backside metal electrode 28 is disposed under the substrate 26. The backside metal electrode 28 may be made of metal.

From a top view, the shape of the P-type window layer 14 is not limited to shapes such as circular, quasi-circular, or elliptical, and may also be other shapes such as triangle, quadrilateral, and pentagon. Any shape that can achieve the corresponding effect may be used.

Please refer to FIG. 3 to FIG. 10, FIG. 3 to FIG. 10 are schematic structural views of the light emitting diode shown in FIG. 2 at various stages during a preparation process.

First, as shown in FIG. 3, the epitaxial structure 12 is grown on the substrate 10, and the epitaxial structure 12 includes the N-type semiconductor layer 123, the light emitting layer 122, and the P-type semiconductor layer 121 stacked in sequence on the substrate 10. The substrate 10 may be made of a transparent material or a semi-transparent material. In some embodiments, the substrate 10 may be a patterned sapphire substrate 10, but the disclosure is not limited thereto. The substrate 10 may also be made of conductive material or semiconductor material. For example, the material of the substrate 10 may include at least one of silicon carbide, silicon, magnesium aluminum oxide, magnesium oxide, lithium aluminum oxide, aluminum gallium oxide, and gallium nitride.

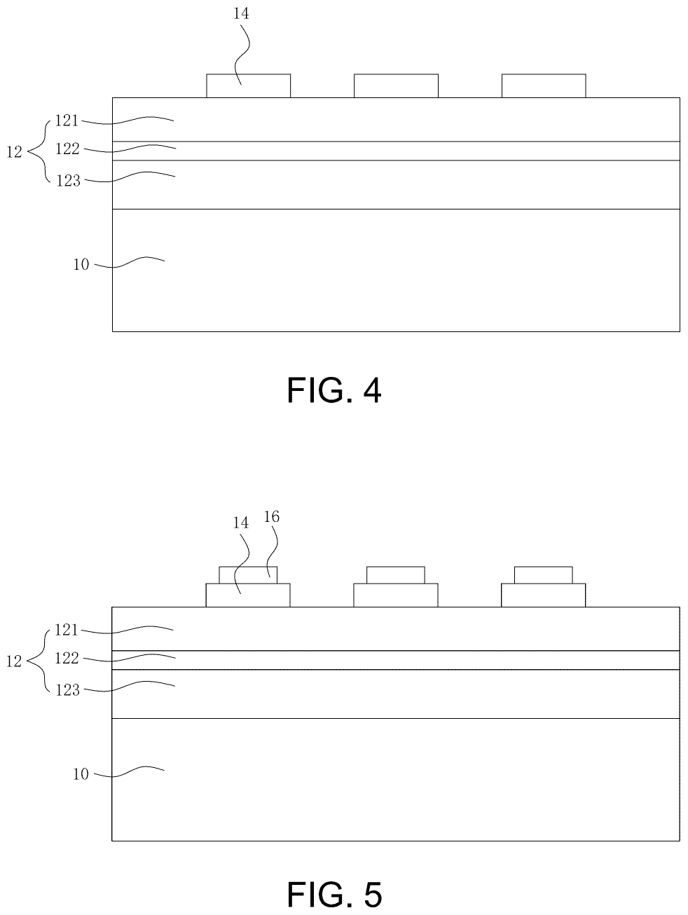

Next, as shown in FIG. 4, a plurality of P-type window layers 14 are disposed on the P-type semiconductor layer 121, and the plurality of P-type window layers 14 are disposed at intervals from each other.

Then, as shown in FIG. 5, a corresponding transparent conductive layer 16 is disposed on each P-type window layer 14, and the width W1 of the transparent conductive layer 16 needs to be less than the width W2 of the P-type window layer 14.

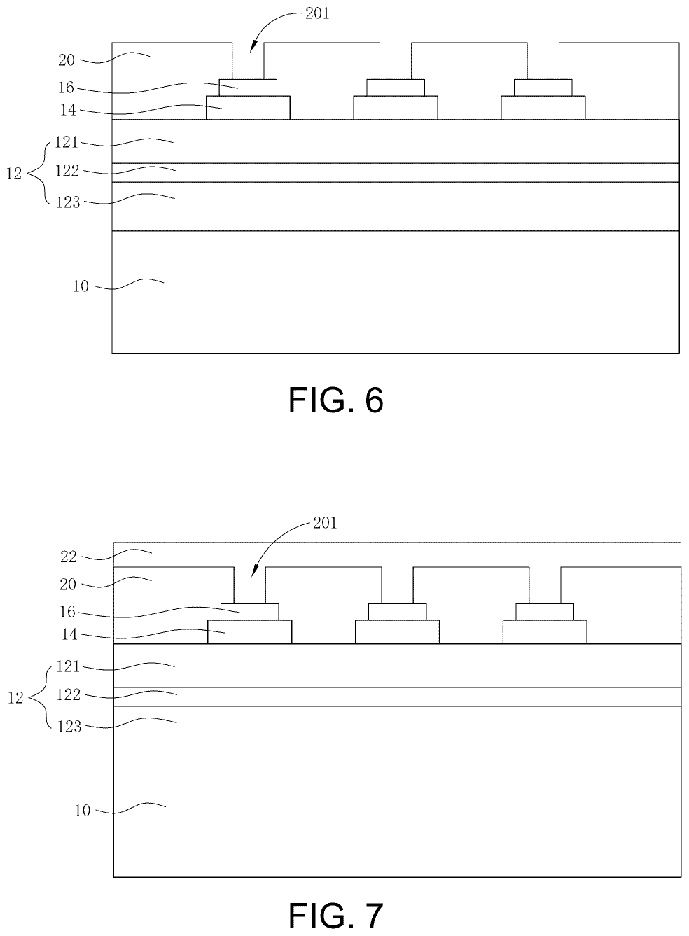

Next, as shown in FIG. 6, the insulative protective layer 20 is disposed on the P-type semiconductor layer 121, the P-type window layer 14, and the transparent conductive layer 16. The insulative protective layer 20 has the opening 201 exposing the transparent conductive layer 16.

Next, as shown in FIG. 7, the metal reflection layer 22 is disposed on the insulative

protective layer 20, and the metal reflection layer 22 is connected to the transparent conductive layer 16 through the opening 201 of the insulative protective layer 20.

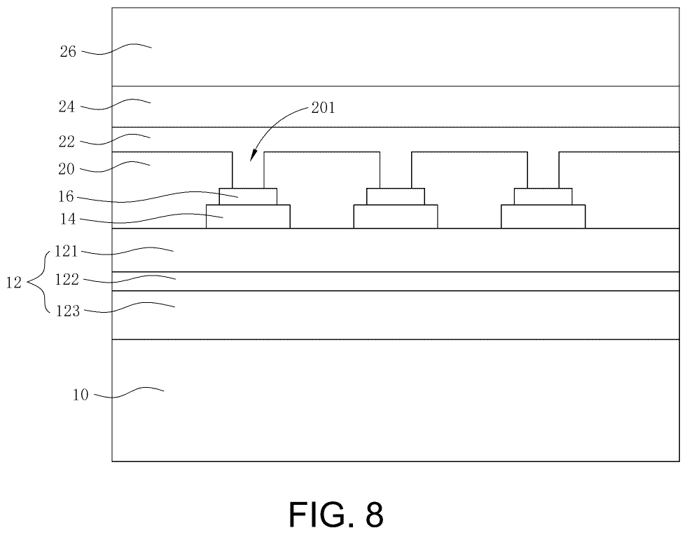

Next, as shown in FIG. 8, the bond layer 24 and the substrate 26 are disposed in sequence on the metal reflection layer 22.

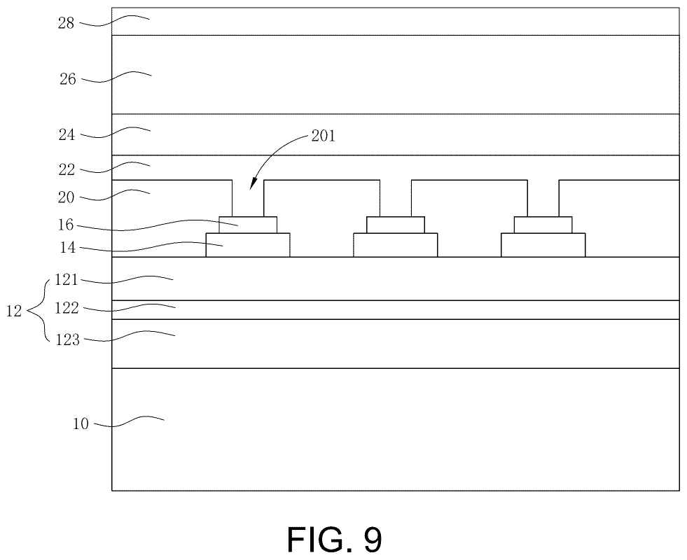

Then, as shown in FIG. 9, the backside metal electrode 28 is disposed on the substrate 26.

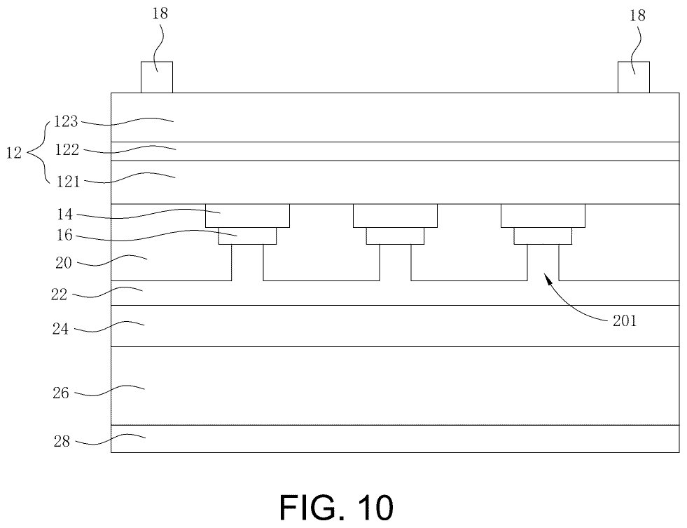

Next, as shown in FIG. 10, the entire structure is first turned over to remove the substrate 10 located on a side of the N-type semiconductor layer 123; and then the N-type electrode 18 is disposed on the surface of the N-type semiconductor layer 123.

An embodiment of the disclosure further provides a light emitting device, which may adopt the light emitting diode provided by any of the above embodiments.

After experimental validation, when the minimum spacing L of the light-emitting diode is reduced from 32.35 μm to 16.52 μm, the ratio of L:J is in the range of 0.3 to 1.5, the voltage at a current of 350 mA drops from 1.952 V to 1.923 V, and the voltage at a current of 700 mA drops from 2.124 V to 2.074 V. In other words, the operating voltage can be reduced and the wall-plug-efficiency of the light emitting diode can be improved.

In summary, an embodiment of the disclosure provides the light emitting diode and the light emitting device, which reduces the operating voltage by controlling the ratio of the spacing to the current density to be set in a range of 0.3 to 1.5, thereby improving the wall-plug-efficiency of the light emitting diode and improving the quality of the light emitting diode.

In addition, persons skilled in the art should understand that, although there are many problems in the related art, each embodiment or technical solution of the disclosure may be improved in only one or several aspects without having to solve all technical problems listed in the related art or background technology at the same time. It should be understood by persons skilled in the art that any content not mentioned in a claim should not be regarded as limiting the claim.

Finally, it should be noted that the embodiments are only used to illustrate the technical solutions of the disclosure, rather than to limit the disclosure. Although the disclosure has been described in detail with reference to the embodiments, persons skilled in the art should understand that the technical solutions described in the embodiments may still be modified, or some or all of the technical features thereof may be replaced by equivalents. However, the modifications or substitutions do not make the essence of the corresponding technical solutions deviate from the scope of the technical solutions of the embodiments of the disclosure.

What is claimed is:

1. A light emitting diode, comprising:
an epitaxial structure, wherein the epitaxial structure comprises a P-type semiconductor layer, a light emitting layer, and an N-type semiconductor layer stacked in sequence from bottom to top;
at least one P-type window layer disposed under the P-type semiconductor layer;
a transparent conductive layer disposed under the P-type window layer; and
at least one N-type electrode disposed on the N-type semiconductor layer,
wherein a current density of the light emitting diode is defined as J A/cm², a minimum spacing between a projection of the N-type electrode on the N-type semiconductor layer and a projection of the P-type window layer on the N-type semiconductor layer is L μm, and a range of L:J is 0.3 to 1.5.

2. The light emitting diode according to claim 1, wherein when the current density is less than 27 A/cm², the minimum spacing is in a range of 10 μm to 25 μm.

3. The light emitting diode according to claim 1, wherein when the current density is greater than 27 A/cm², the minimum spacing is in a range of 15 μm to 30 μm.

4. The light emitting diode according to claim 1, wherein the minimum spacing is in a range of 10 μm to 30 μm.

5. The light emitting diode according to claim 1, wherein a width of the transparent conductive layer is less than or equal to a width of the P-type window layer.

6. The light emitting diode according to claim 5, wherein the width of the P-type window layer is 10 μm to 30 μm.

7. The light emitting diode according to claim 1, wherein a thickness of the N-type semiconductor layer is in a range of 2 μm to 4 μm.

8. The light emitting diode according to claim 1, wherein a thickness of the P-type window layer is 200 angstroms to 3000 angstroms.

9. The light emitting diode according to claim 1, wherein a quantity of the at least one N-type electrode is plural, and a spacing between two adjacent ones of the N-type electrodes is in a range of 90 μm to 130 μm.

10. The light emitting diode according to claim 1, wherein a quantity of the at least one P-type window layer is plural, and a spacing between two adjacent ones of the P-type window layers is in a range of 5 μm to 15 μm.

11. The light emitting diode according to claim 1, further comprising an insulative protective layer, a metal reflection layer, a bond layer, a substrate, and a backside metal electrode, wherein the insulative protective layer covers the P-type semiconductor layer, the P-type window layer, and the transparent conductive layer, the insulative protective layer has an opening, the metal reflection layer is disposed under the insulative protective layer and connected to the transparent conductive layer through the opening, the bond layer is disposed under the metal reflection layer, the substrate is disposed under the bond layer, and the backside metal electrode is disposed under the substrate.

12. A light emitting device adopting the light emitting diode according to claim 1.
